(19) United States
(12) Patent Application Publication
(10) Pub. No.: US 2025/0309632 A1
(43) Pub. Date: Oct. 2, 2025

(54) SHORT CIRCUIT PROTECTION WITH TEMPERATURE COMPENSATION

(71) Applicant: Texas Instruments Incorporated, Dallas, TX (US)

(72) Inventors: Abhijeet Godbole, BANGALORE (IN); Durga Praveen Gorrela, BANGALORE (IN)

(21) Appl. No.: 18/619,413

(22) Filed: Mar. 28, 2024

(51) Int. Cl. H02H 3/08

(52) U.S. Cl. CPC H02H 3/08

(57) ABSTRACT

Described embodiments include a circuit for overcurrent protection includes an amplifier having first and second amplifier inputs and an amplifier output. A reference voltage source has first and second reference voltage terminals and is configured to provide a reference voltage. The first reference voltage terminal is adapted to be coupled to a first transistor current terminal, and the second reference voltage terminal is coupled to the first amplifier input. A negative temperature coefficient (NTC) resistor has first and second NTC terminals. The first NTC terminal is adapted to be coupled to a second transistor current terminal, and the second NTC terminal is coupled to the second amplifier input. A transistor shutoff signal is provided at the amplifier output responsive to a voltage at the second amplifier input being greater than a voltage at the first amplifier input.

### BACKGROUND

This description relates to short circuit protection in electronic circuits. This description further relates to compensating for changes in the on-resistance of switches in electronic circuits due to temperature effects. Compensating for the change in the on-resistance of a switch can help provide more accurate current sensing for detecting short circuit and overcurrent conditions, particularly in cases where the switches may be operating in high temperature or low temperature conditions.

Two typical methods of sensing current in short circuit protection circuits are resistor-based current sensing and V_{DS}-based current sensing, which uses a field effect transistor (FET). Resistor-based current sensing is usually more accurate than V_{DS}-based current sensing. In one example, a short circuit protection circuit using resistor-based current sensing was measured to have a variation from 0.1-10% accuracy over the temperature range −40 C to 150 C, while a short circuit protection circuit using V_{DS}-based current sensing can vary more than 100% over the same temperature range.

However, a drawback of resistor-based current sensing is that it typically also has a significantly higher cost than V_{DS}-based current sensing and has a higher power consumption. V_{DS}-based current sensing typically does not require an external resistor because the current is sensed by measuring the voltage across the FET and dividing that voltage by a known on-resistance of the FET. So, V_{DS}-based current sensing provides a lower cost and lower power consumption, but the accuracy is lower across the temperature range because the on-resistance of the FET changes with temperature, and this is not typically compensated for.

### SUMMARY

In a first example, a circuit for overcurrent protection includes an amplifier having first and second amplifier inputs and an amplifier output. A reference voltage source has first and second reference voltage terminals and is configured to provide a reference voltage. The first reference voltage terminal is adapted to be coupled to a first transistor current terminal, and the second reference voltage terminal is coupled to the first amplifier input.

A negative temperature coefficient (NTC) resistor has first and second NTC terminals. The first NTC terminal is adapted to be coupled to a second transistor current terminal, and the second NTC terminal is coupled to the second amplifier input. A transistor shutoff signal is provided at the amplifier output responsive to a voltage at the second amplifier input being greater than a voltage at the first amplifier input.

In a second example, a system includes a transistor having first and second transistor current terminals and a transistor control terminal. An amplifier has first and second amplifier inputs and an amplifier output. A reference voltage source has first and second reference voltage terminals, and is configured to provide a reference voltage. The first reference voltage terminal is coupled to the first transistor current terminal, and the second reference voltage terminal is coupled to the first amplifier input.

A negative temperature coefficient (NTC) resistor has first and second NTC terminals. The first NTC terminal is coupled to the second transistor current terminal. A temperature offset circuit has a temp offset input and a temp offset output. The temp offset input is coupled to the second NTC terminal, and the temp offset output is coupled to the second amplifier input.

### BRIEF DESCRIPTION OF THE DRAWINGS

FIG. 1 shows a graph for an example curve of on-resistance versus junction temperature for a typical field effect transistor.

FIG. 2 shows a schematic diagram for an example V_{DS}-sensing overcurrent protection circuit.

FIG. 3 shows a block diagram for an example V_{DS}-sensing overcurrent protection circuit with temperature compensation.

FIG. 4 shows a schematic diagram for an example V_{DS}-sensing overcurrent protection circuit with temperature compensation having dual resistor settings.

### DETAILED DESCRIPTION

In this description, the same reference numbers depict same or similar (by function and/or structure) features. The drawings are not necessarily drawn to scale.

Circuits designed to carry relatively large amounts of current may have a requirement for the inclusion a short circuit protection or overcurrent protection circuit to prevent damage to components due to excessive current. Two traditional methods for implementing overcurrent protection or short circuit protection in the power path of a circuit include resistor-based current sensing overcurrent protection and V_{DS}-sensing overcurrent protection. The resistor-based current sensing overcurrent protection is more accurate than V_{DS}-sensing overcurrent protection, while V_{DS}-sensing overcurrent protection typically provides a lower cost and lower power solution than resistor-based current sensing overcurrent protection.

V_{DS}-sensing overcurrent protection uses the voltage drop from the drain to the source (V_{DS}) of a field effect transistor (FET) in the power path of the circuit to determine the current through the FET. The load current flowing through the FET into the on-resistance of the FET (R_{DSON}) produces a voltage drop V_{DS} across the FET. The voltage drop V_{DS} across the FET divided by the R_{DSON} of the FET is the current through the FET. However, the accuracy of the current determination by measurement of V_{DS} is only as accurate as the accuracy of the value for R_{DSON}. Any inaccuracy in the value of R_{DSON} translates linearly into an error in the current

The voltage V_{DS} is compared to a threshold reference voltage that represents the overcurrent threshold. If the V_{DS} across the FET exceeds the threshold reference voltage, a short circuit or overcurrent condition is declared, and the system can be shut down to help protect against damage from an overcurrent. Overcurrent protection using V_{DS}-sensing is usually less expensive than resistor-based current sensing because it does not require an additional current sense resistor.

However, a drawback to overcurrent protection using V_{DS}-sensing is that the R_{DSON} of a FET can change significantly over a wide temperature range. In many cases, a R_{DSON} value of the FET is determined at 25 C, and that value is used for R_{DSON} in calculating the current through the FET. However, the R_{DSON} does not remain constant over temperature, and may change 2× over a temperature range from −40 C to 150 C. In some cases, the R_{DSON} value may vary 2.8× or 3× over that temperature range. Because the R_{DSON} is changing so much, the V_{DS}, which is equal to R_{DSON}*I_{LOAD}, also changes proportionally with temperature, bringing error to the current measurement as the temperature of the FET changes.

As a result, the short circuit current protection will trigger or activate at a higher short circuit current when operating at lower temperatures because the R_{DSON} of the FET decreases as the temperature decreases. This means that with the same current through the FET, the V_{DS} is lower at cold temperatures than it is at room temperature, so it takes more current to reach the same V_{DS}. Conversely, the short circuit current protection will trigger at lower short circuit currents when operating at higher temperatures because the R_{DSON} of the FET increases as the temperature increases. This means that with the same current through the FET, the V_{DS} is higher at hot temperatures than it is at room temperature, so it takes less current to reach the same V_{DS}. That creates an issue that while designing for a particular fixed short circuit current threshold, if the R_{DSON} can vary as much as 2× or 3×, the system must either be designed for the worst case or accept the errors caused by the temperature variance in the short circuit current detection.

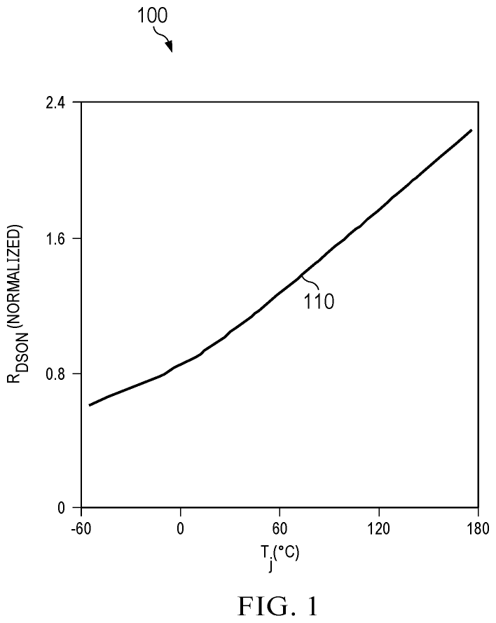

FIG. 1 shows a graph 100 of an example curve 110 for on-resistance versus junction temperature for a typical FET. The x-axis of graph 100 is the junction temperature (T_{J}) of the FET. The y-axis of graph 100 is the on-resistance of the FET (R_{DSON}) normalized at a temperature of 25 C. Curve 110 is a plot of R_{DSON} as a function of the junction temperature of the FET. Because the y-axis is normalized at 25 C, the value of R_{DSON} at 25 C is 1.0. Curve 110 shows that the R_{DSON} is about twice the value at 150 C as it is at 25 C. Curve 110 also shows that the R_{DSON} is about half the value at −60 C as it is at 25 C. So, the R_{DSON} of the typical FET shown in graph 100 has a variation of a factor of four from −60 C to 150 C.

This means that FETs with a higher safe operating area (SOA) may be required to ensure the safe operation of the devices. Using FETs with a higher SOA can increase the cost significantly. An alternative to using FETs with a higher SOA is to use an external current sense resistor-based current sensing, but that adds to the power consumption and the system cost of both the controller and the sense resistor, making the solution unattractive from a power and cost standpoint. A low-cost short circuit current detection circuit that provides acceptable accuracy over a wide temperature range can be a valuable improvement.

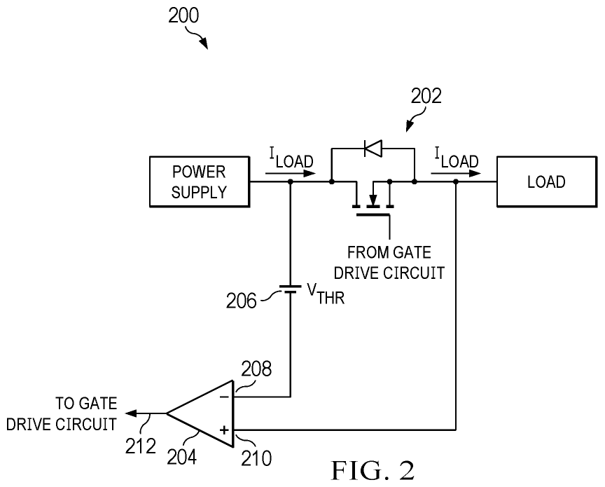

FIG. 2 shows a schematic diagram for an example V_{DS}-sensing overcurrent protection circuit 200. FET 202 is coupled between a first terminal of a voltage reference source 206 and a first input 210 of amplifier 204. In at least one example, amplifier 204 is replaced by a comparator. A second input 208 of amplifier 204 is coupled to a second terminal of voltage reference source 206. Voltage reference source 206 provides a fixed reference voltage V_{THR} that represents the short circuit current threshold. Amplifier 204 has an output 212 that provides a signal indicating whether the current through FET 202 has exceeded the short circuit current threshold.

The drain of FET 202 is coupled to the first terminal of the voltage reference source 206, and a source of FET 202 is coupled to the first input of amplifier 204. The gate of FET 202 is coupled to an output of a gate drive circuit (not shown) and receives a gate control signal from the gate drive circuit. The output 212 of amplifier 204 is coupled to an input of the gate drive circuit (not shown). The voltage at the drain of FET 202 is added to the reference voltage V_{THR} from voltage reference source 206 and is provided to the second input 208 of amplifier 204. The voltage at the source of FET 202 is provided to the first input 210 of amplifier 204.

If the voltage between the drain and source of FET 202 (V_{DS}) exceeds the reference voltage V_{THR} from voltage reference source 206, the output 212 of amplifier 204 will provide a signal indicating that a short circuit condition has been detected. A signal from the output 212 of amplifier 204 is provided to the gate drive circuit (not shown) to initiate turning off FET 202 in response to the short circuit condition. This protects FET 202 and other circuitry from being damaged by a higher than allowable current.

The reference voltage V_{THR} is chosen to be equal to the voltage V_{DS} at the specified short circuit threshold current based on FET 202 having a constant R_{DSON} that is determined at a single calibration temperature. In at least one case, the calibration temperature is 25 C. However, the R_{DSON} varies as a function of the temperature as the temperature changes, and the R_{DSON} value that is determined at the calibration temperature will be in error for any other temperature. As the actual temperature gets farther from the calibration temperature, the error in V_{DS}-sensing overcurrent protection circuit 200 will increase.

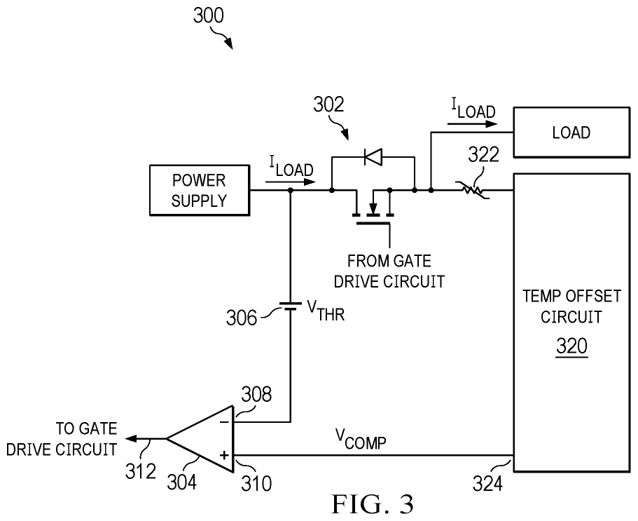

FIG. 3 shows a block diagram for a V_{DS}-sensing overcurrent protection circuit with temperature compensation 300. FET 302 is coupled between a first terminal of a voltage reference source 306 and a first input 310 of amplifier 304. In at least one example, amplifier 304 is replaced by a comparator. A second terminal 308 of amplifier 304 is coupled to a second terminal of voltage reference source 306. Voltage reference source 306 provides a fixed reference voltage V_{THR} that represents a short circuit current threshold. Amplifier 304 has an output 312 that provides a signal indicating whether the current through FET 302 has exceeded the short circuit current threshold.

Resistor 322 is a negative temperature coefficient resistor, and has a first terminal coupled to the source of FET 302. A negative temperature coefficient (NTC) resistor is a resistor that decreases in resistance as its temperature increases, and increases in resistance as its temperature decreases. An NTC resistor behaves in an opposite manner with temperature compared to a traditional resistor which increases in resistance as its temperature increases and decreases in resistance as its temperature decreases. NTC resistor 322 is preferably placed in relatively close proximity to FET 302 so that the temperature of NTC resistor 322 is approximately the same as the temperature of FET 302. In this manner, the resistance of NTC resistor 322 will change proportionally with changes in the R_{DSON} of FET 302 due to temperature, but in the opposite direction.

Temperature offset circuit 320 has an input coupled to a second terminal of NTC resistor 322, and has an output coupled to the first input 310 of amplifier 304. Temperature offset circuit 320 includes a current source that in conjunction with NTC resistor 322 creates an offset voltage VCOMP 324 that adjusts the difference between the V_{DS} of FET 302 and the short circuit protection threshold voltage V_{THR} to compensate for the difference in temperature between the calibration temperature of the short circuit protection circuit and the current temperature. Based on the temperature of FET 302, a variable offset voltage VCOMP 324 is added to the voltage from the source of FET 302 to linearize the short circuit threshold protection response. In at least one other case, the variable offset voltage VCOMP 324 can instead be subtracted from the short circuit protection threshold voltage V_{THR}.

NTC resistor 322 has a lower resistance at 125 C than it does at 25 C, and has a higher resistance at −40 C than it does at 25 C. The resistance of NTC resistor 322 changes in the opposite direction as the R_{DSON} of FET 302 in response to changes in temperature. The temperature dependent element, NTC resistor 322, combined with a current source in temperature offset circuit 320, generates an offset voltage that is subtracted from the short circuit protection threshold voltage V_{THR} to compensate for the temperature dependence of the R_{DSON} of FET 302.

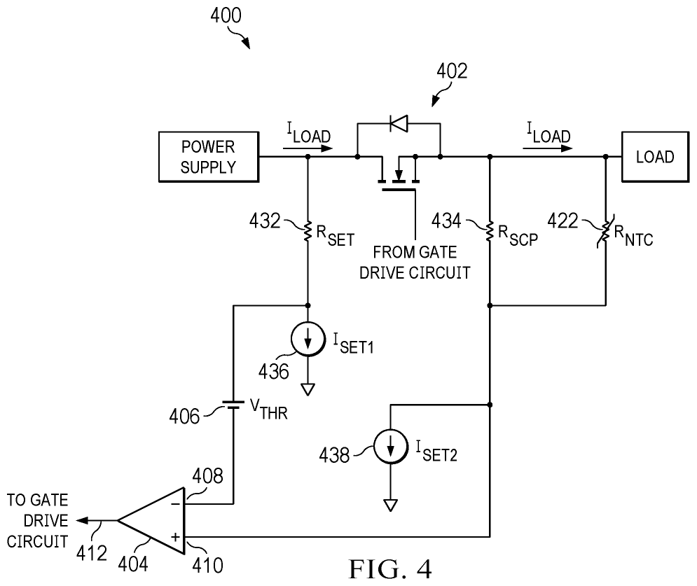

FIG. 4 shows a schematic diagram for an example V_{DS}-sensing overcurrent protection circuit 400 with temperature compensation having dual resistor settings. FET 402 has a source, a drain and a gate. The gate of FET 402 is coupled to a gate drive circuit (not shown) and receives a gate control signal from the gate drive circuit. Resistor 432 has a first terminal coupled to the drain of FET 402, and a second terminal coupled to a first terminal of voltage reference source 406. Voltage reference source 406 provides a fixed reference voltage V_{THR} that represents a short circuit current threshold at a calibrated temperature. In at least one case, the calibration temperature is 25 C, but it could be at another temperature. Current source I_{SET1} 436 is coupled between the second terminal of resistor 432 and a ground terminal, and it provides a current I_{SET1}.

Resistor 434 has a first terminal coupled to the source of FET 402, and a second terminal coupled to a first input 410 of amplifier 404. NTC resistor 422 is coupled in parallel with resistor 434 between the source of FET 402 and the first input 410 of amplifier 404. In at least one example, amplifier 404 is replaced by a comparator. A second terminal 408 of amplifier 404 is coupled to a second terminal of voltage reference source 406.

Current source 438 is coupled between the first input 410 of amplifier 404 and the ground terminal, provides a current I_{SET2}. In at least one example, current source I_{SET2} 438 is configured to provide the same magnitude of current as current source I_{SET1} 436. However, in many other examples, the magnitude of current provided by current source I_{SET1} 436 is different than the magnitude of current provided by current source I_{SET2} 438. Amplifier 404 has an output 412 that provides a signal indicating whether the current through FET 402 has exceeded the short circuit current threshold.

NTC resistor 422 senses the temperature of FET 402, so it is preferably located as close to FET 402 as possible to improve the accuracy of its temperature sensing. V_{DS}-sensing overcurrent protection circuit 400 has two resistors for adjusting the short circuit current threshold from the nominal voltage V_{THR} set by voltage reference source 406. The first adjustment resistor is resistor 432, which has a resistance of R_{SET}. As the resistance R_{SET} of resistor 432 is increased, the reference voltage threshold is increased to a value higher than V_{THR}. Current source 436 provides a current of I_{SET} that flows through resistor 432 with a resistance of R_{SET}, increasing the threshold voltage by an amount equal to R_{SET}*I_{SET1}. So, the compensated threshold voltage augmented by the current I_{SET1} and R_{SET} is given by equation (1):

V_{THRCOMP}=V_{THR}+R_{SET}*I_{SET1} (1)

The second adjustment resistor is resistor 434 having a resistance of R_{SCP}. As the resistance R_{SCP} of resistor 434 is increased, the reference voltage threshold is decreased to a value lower than V_{THR}. Current source 438 provides a current of I_{SET2} that flows through resistor 434 with a resistance of R_{SCP}, decreasing the short circuit protection threshold voltage by an amount equal to R_{SCP}*I_{SET2}. To reduce the threshold by an amount equal to R_{SCP}*I_{SET2}, resistor 434 will have a value of R_{SCP} and the resistance R_{SET} of resistor 432 is set to 0 ohms.

NTC resistor 422 has a resistance of R_{NTC} and is coupled in parallel with resistor 434, which has a resistance of R_{SCP}. The current I_{SET2} from current source 438 flows through the parallel resistance of resistor 434 and NTC resistor 422. The resistance of the parallel combination of resistor 434 with NTC resistor 422 is calculated using equation (2):

R_{SCP}//R_{NTC}=(R_{SCP}*R_{NTC})/(R_{SCP}+R_{NTC}) (2)

Resistor 432 R_{SET} and resistor 434 R_{SCP} are used to increase or decrease, respectively, the short circuit protection threshold voltage. NTC resistor 422 provides a temperature dependent offset voltage to compensate the short circuit protection threshold voltage. The short circuit protection threshold voltage V_{SCPTH} is calculated using equation (3):

V_{SCPTH}=V_{THR}+(R_{SET}*I_{SET}1)−((R_{SCP}*R_{NTC})/(R_{SCP}+R_{NTC})*I_{SET2}) (3)

The short circuit protection threshold voltage V_{SCPTH} can be compensated for temperature using current sources I_{SET1} 436 and I_{SET2} 438 in conjunction with resistors 432 R_{SET}, 434 R_{SCP} and 422. The resistance R_{NTC} of NTC resistor 422 varies with temperature, while the resistances of resistor 432 R_{SET} and resistor 434 R_{SCP} are fixed. The only value that is changing in equation (3) is R_{NTC} which varies with temperature as the R_{DSON} of FET 402 varies in the opposite direction. V_{DS}-sensing overcurrent protection circuit 400 counteracts and compensates for changes in the R_{DSON} of FET 402 due to temperature, allowing a more accurate short circuit current protection threshold to be obtained.

At hot temperatures (e.g. 150 C), the resistance R_{NTC} of NTC resistor 422 is near zero (i.e. a few ohms), which effectively bypasses resistor 434 R_{SCP}. So, at temperatures near 150 C, the short circuit protection threshold voltage, V_{SCPTHH}, is calculated using equation (4):

V_{SCPTHH}=V_{THR}+(R_{SET}*I_{SET1}) (4)

At cold temperatures (e.g. −40 C), the resistance R_{NTC} of NTC resistor 422 will be high (i.e. megohms), which effectively makes NTC resistor 422 act as an open circuit, and NTC resistor 422 will have no practical effect on the short circuit protection threshold voltage. So, the short circuit protection threshold voltage at cold temperatures, V_{SCPTHC}, is calculated using equation (5):

V_{SCPTHC}=V_{THR}+(R_{SET}*I_{SET1})−(R_{SCP}*I_{SET2}) (5)

Typical types of systems that may benefit from V_{DS}-sensing overcurrent protection circuit 400 include automotive applications, such as advanced driver assistance systems, infotainment and clusters, body control and lighting. A V_{DS}-sensing overcurrent protection circuit with temperature compensation can be useful in applications requiring an ideal diode for protection against damage due to a reverse polarity connection of battery terminals. A V_{DS}-sensing overcurrent protection circuit with temperature compensation may also be useful in industrial electronics, personal electronics, or any application having a switch configuration with a high surge current.

The V_{DS}-sensing overcurrent protection circuit 400 adds or subtracts a temperature dependent offset to the short circuit comparator reference voltage V_{THR} to compensate for changes in the R_{DSON} of a switch in the power path of the circuit. In one example, the variation of accuracy in current measurements across a temperature range of −40 C to 125 C improved by a factor of twelve.

The V_{DS}-sensing overcurrent protection circuit 400 reduces the need for an external current sensing resistor in order to achieve a specified accuracy in measurement of the current through the switch. Furthermore, the V_{DS}-sensing overcurrent protection circuit 400 provides lossless current sensing, which may be of value in high power systems. A FET with a lower SOA can be used safely and reliably, providing significant cost savings. The system benefits from V_{DS}-sensing overcurrent protection circuit 400 include low cost power path overcurrent protection without an external current sense resistor.

In this description, “terminal,” “node,” “interconnection,” “lead” and “pin” are used interchangeably. Unless specifically stated to the contrary, these terms generally mean an interconnection between or a terminus of a device element, a circuit element, an integrated circuit, a device, or other electronics or semiconductor component.

In this description, “ground” includes a chassis ground, an Earth ground, a floating ground, a virtual ground, a digital ground, a common ground and/or any other form of ground connection applicable to, or suitable for, the teachings of this description.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, so device B is controlled by device A via the control signal generated by device A.

In this description, even if operations are described in a particular order, some operations may be optional, and the operations are not necessarily required to be performed in that particular order to achieve specified results. In some examples, multitasking and parallel processing may be advantageous. Moreover, a separation of various system components in the embodiments described above does not necessarily require such separation in all embodiments.

Modifications are possible in the described embodiments, and other embodiments are possible, within the scope of the claims.

What is claimed is:

1. A circuit for overcurrent protection comprising:
an amplifier having first and second amplifier inputs and an amplifier output;
a reference voltage source having first and second reference voltage terminals and configured to provide a reference voltage, wherein the first reference voltage terminal is adapted to be coupled to a first transistor current terminal, and the second reference voltage terminal is coupled to the first amplifier input; and
a negative temperature coefficient (NTC) resistor having first and second NTC terminals, wherein the first NTC terminal is adapted to be coupled to a second transistor current terminal, and the second NTC terminal is coupled to the second amplifier input;
wherein a transistor shutoff signal is provided at the amplifier output responsive to a voltage at the second amplifier input being greater than a voltage at the first amplifier input.

2. The circuit of claim 1, further comprising a resistor having first and second resistor terminals, wherein the first resistor terminal is adapted to be coupled to the first transistor current terminal, and the second resistor terminal is coupled to the first reference voltage terminal.

3. The circuit of claim 2, further comprising a current source coupled between the second resistor terminal and a ground terminal.

4. The circuit of claim 3, wherein the resistor is a first resistor, the current source is a first current source, and the circuit is further comprising:
a second resistor coupled in parallel with the NTC resistor; and
a second current source coupled between the second NTC terminal and the ground terminal.

5. The circuit of claim 4, wherein the amplifier is configured as a comparator.

6. The circuit of claim 1, wherein the reference voltage corresponds to an overcurrent limit threshold.

7. The circuit of claim 4, wherein the first current source and the second current source provide a same magnitude of current.

8. The circuit of claim 1, wherein a voltage at the second amplifier input decreases when a temperature of the NTC resistor decreases.

9. The circuit of claim 8, wherein the voltage at the second amplifier input increases when the temperature of the NTC resistor increases.

10. The circuit of claim 1, further comprising a gate drive circuit having a gate drive input and a gate drive output, wherein the gate drive input is coupled to the amplifier output, and the gate drive output is adapted to be coupled to a transistor control terminal.

11. A system comprising:
a transistor having first and second transistor current terminals and a transistor control terminal;
an amplifier having first and second amplifier inputs and an amplifier output;
a reference voltage source having first and second reference voltage terminals and configured to provide a reference voltage, wherein the first reference voltage terminal is coupled to the first transistor current terminal, and the second reference voltage terminal is coupled to the first amplifier input;
a negative temperature coefficient (NTC) resistor having first and second NTC terminals, wherein the first NTC terminal is coupled to the second transistor current terminal; and
a temperature offset circuit having a temp offset input and a temp offset output, wherein the temp offset input is coupled to the second NTC terminal, and the temp offset output is coupled to the second amplifier input.

12. The system of claim 11, further comprising a gate drive circuit having a gate drive input and a gate drive output, wherein the gate drive input is coupled to the amplifier output, the gate drive output is coupled to the transistor control terminal, and the gate drive circuit is configured to control the transistor to shut off responsive to a voltage at the second amplifier input being greater than a voltage at the first amplifier input.

13. The system of claim 11, wherein the temperature offset circuit includes:
a resistor coupled in parallel with the NTC resistor; and
a current source coupled between the second NTC terminal and a ground terminal.

14. The system of claim 13, wherein the resistor is a first resistor, the current source is a first current source, and the system is further comprising:
a second resistor having first and second resistor terminals, wherein the first resistor terminal is coupled to the first transistor current terminal, and the second resistor terminal is coupled to the first reference voltage terminal; and
a second current source coupled between the second resistor terminal and the ground terminal.

15. The system of claim 11, wherein the amplifier is configured as a comparator.

16. The system of claim 11, wherein the reference voltage corresponds to an overcurrent limit threshold.

17. The system of claim 14, wherein the first current source and the second current source provide a same magnitude of current.

18. The system of claim 11, wherein a voltage at the second amplifier input decreases when a temperature of the NTC resistor decreases.

19. The system of claim 18, wherein the voltage at the second amplifier input increases when the temperature of the NTC resistor increases.

20. The system of claim 11, wherein the NTC resistor is located proximate the transistor.
